(19) United States
(12) Patent Application Publication
(10) Pub. No.: US 2014/0291832 A1
(43) Pub. Date: Oct. 2, 2014

(54) INTEGRATED COOLING MODULES OF POWER SEMICONDUCTOR DEVICE

(71) Applicant: Infineon Technologies AG, Neubiberg (DE)

(72) Inventor: Alexander Schwarz, Moehnesee (DE)

(73) Assignee: Infineon Technologies AG, Neubiberg (DE)

(21) Appl. No.: 13/852,141

(22) Filed: Mar. 28, 2013

(51) Int. Cl. H01L 23/46; H01L 21/48; H01L 23/473

(52) U.S. Cl. CPC H01L 23/46; H01L 23/473; H01L 21/4871
USPC 257/714; 257/712; 438/122

(57) ABSTRACT

A semiconductor module is disclosed having at least one power semiconductor device, wherein the at least one power semiconductor device has first and second planar sides; a first thermally conductive substrate in thermal contact with the first planar side of the power semiconductor device; a first cooling module defining a first cavity, the first cavity in thermal contact with the first thermally conductive substrate, and the first cooling module in mechanical connection with the first thermally conductive substrate; a first inlet provided in the first cavity for receiving a coolant; a first outlet provided in the first cavity for discharging said coolant; wherein the power semiconductor device is in coolant-proof isolation from the cavity.

### TECHNICAL FIELD

The disclosure relates to cooling modules integrated with power semiconductor devices, and more particularly to an integrated liquid-cooling module structure.

### BACKGROUND

Power semiconductor devices, such as insulated gate bipolar transistor (IGBT) modules, are utilized in a wide scope of applications, ranging from conventional industrial applications to home-use electronic appliance applications and the like. In many of these applications, heat is generated in the device, and it may be necessary to remove this generated heat from the device.

Typically, heat may be removed from the device with a heat sink. Heat sinks may be constructed from heat conductive material which may absorb heat from the device and then transfer the heat to a surrounding environment. For example, a heat sink comprising a Pin-Fin structure may remove the heat from a power semiconductor module directly. In a more complex example, a heat sink comprising cooling Pin-Fins may further include a fluid flow system for extracting heat from a power semiconductor module. However, the cost of the cooling system is also highly raised due to the utilization of cooling fluid. For example, for a “6 in 1” module package, three power semiconductor modules may be needed for cooling one side of the package, and six such cooling modules may be needed for cooling both sides of the package. In such a design, cost and weight become paramount design considerations.

Another approach of cooling the power semiconductor devices may involve applying thermal grease to the cooler to assist in dissipating the heat form the power semiconductor devices. However, the utilized cooler can be expensive, and besides that, with this approach, it can be difficult for the heat sink to sufficiently dissipate heat from the power semiconductor devices due to high thermal resistance of the thermal grease. In addition, it can be problematic to apply the thermal grease paste flat and smooth to a cooler.

Thus, there is a need in the art to provide a cooling module for a power semiconductor device with low cost, light weighted and easy installation.

### BRIEF SUMMARY

According to an aspect of the present disclosure, a semiconductor module is disclosed having: at least one power semiconductor device, wherein the at least one power semiconductor device has first and second planar sides; a first thermally conductive substrate in thermal contact with the first planar side of the power semiconductor device; a first cooling module defining a first cavity, the first cavity in thermal contact with the first thermally conductive substrate, and the first cooling module in mechanical connection with the first thermally conductive substrate; a first inlet provided in the first cavity for receiving a coolant; a first outlet provided in the first cavity for discharging said coolant; wherein the power semiconductor device is in coolant-proof isolation from the cavity. The power semiconductor device comprises an insulated-gate bipolar transistor (IGBT) in parallel with a diode. The first thermally conductive substrate is a direct copper bonding (DCB) substrate or a direct aluminum bonding (DAB) substrate. The first cooling module is composed of coolant-proof material, e.g. plastic. The coolant is composed of one of gases, liquids, e.g. water, and mixtures of gases, liquids and solids. The semiconductor module further includes an intervening layer composed of mold compound, where power semiconductor device is embedded in. Further, an anchor molded into the intervening layer forms the mechanical connection between the cooling module and the intervening layer.

According to a further aspect of the present disclosure, the semiconductor module disclosed further has: at least one thermally conductive spacer embedded in the intervening layer, the thermally conductive spacer having first and second planar sides, wherein the first planar side of the thermally conductive spacer is bonded to the second planar side of the power semiconductor device; a second thermally conductive substrate in thermal contact with the second planar side of the thermally conductive spacer; a second cooling module defining a second cavity, the second cavity in thermal contact with the second thermally conductive substrate, and the second cooling module in mechanical connection with the second thermally conductive substrate; and a second inlet provided in the second cavity for receiving the coolant; a second outlet provided in the second cavity for discharging the coolant. The intervening layer forms a coplanar surface with the second planar side of the thermally conductive spacer. The second thermally conductive substrate is a direct copper bonding (DCB) substrate or a direct aluminum bonding (DAB) substrate. The second cooling module is composed of coolant-proof material, e.g. plastic. The coolant is composed of one of gases, liquids, e.g. water, and mixtures of gases, liquids and solids.

According to a further aspect of the present disclosure, at least one of the first inlet, the first outlet, the second inlet and the second outlet of the semiconductor module connects to a pump. At least one of the first cooling module and the second cooling module contains cooling fins. Alternatively, at least one of the first cooling module and the second cooling module contains a plurality of channel walls.

According to an aspect of the present disclosure, a method for producing a power semiconductor device with a cooling module is disclosed, including: providing the power semiconductor device on a first side of a thermally conductive substrate, wherein the thermally conductive substrate has a first perimeter; connecting the cooling module mechanically on a second side of the thermally conductive substrate, wherein the cooling module has at least one protruding structure extending in the direction from the second side to the first side of the thermally conductive substrate; and embedding the power semiconductor device into a mold compound, wherein the mold compound engages at least part of the at least one protruding structure, physically joins the cooling module to the thermally conductive substrate into a single package, and provides a coolant-proof seal between the cooling module and the thermally conductive substrate.

### BRIEF DESCRIPTION OF THE DRAWINGS

The drawings are not necessarily to scale, emphasis instead generally being placed upon illustrating the principles of the present disclosure. For the purpose of illustrating the disclosure, there are shown in the drawing aspects of the present disclosure. It should be understood, however, that the disclosure is not limited to the precise arrangement and instrumentalities shown. In the drawing:

FIG. 1A shows a cross-sectional view of a power semiconductor module according to an exemplary embodiment of the disclosure.

FIG. 1B shows a detailed view of mechanical connection according to the exemplary embodiment shown in FIG. 1A.

FIG. 1C shows a perspective view of a power semiconductor module with double-sided cooling modules of FIG. 1 according to an exemplary embodiment of the disclosure.

FIG. 2 shows a cross-sectional view of a power semiconductor module according to another exemplary embodiment of the disclosure.

FIG. 3 shows a cross-sectional view of a power semiconductor module according to another exemplary embodiment of the disclosure.

FIG. 4 shows a top cross-sectional view of a cooling module part according to an exemplary embodiment of the disclosure.

FIG. 5 shows a top cross-sectional view of a cooling module part according to another exemplary embodiment of the disclosure.

FIG. 6A is a flow chart of a method for producing a power semiconductor module with a cooling module.

FIG. 6B is a flow chart of a further method for producing a power semiconductor module with a cooling module.

FIG. 7 is a flow chart of a method for producing a power semiconductor module with a cooling module.

### DETAILED DESCRIPTION

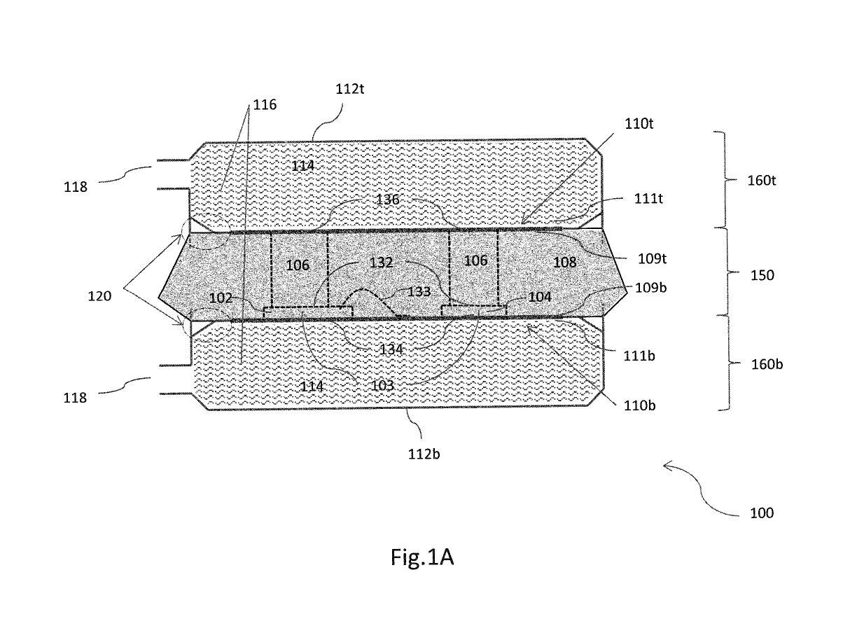

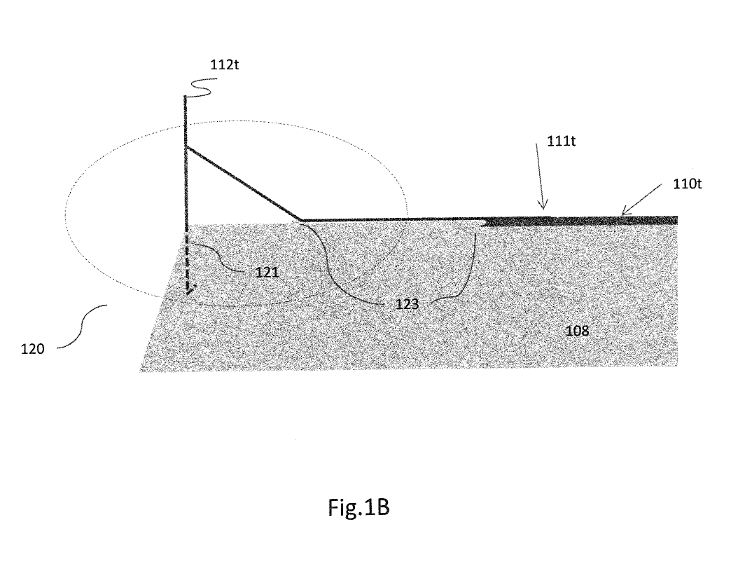

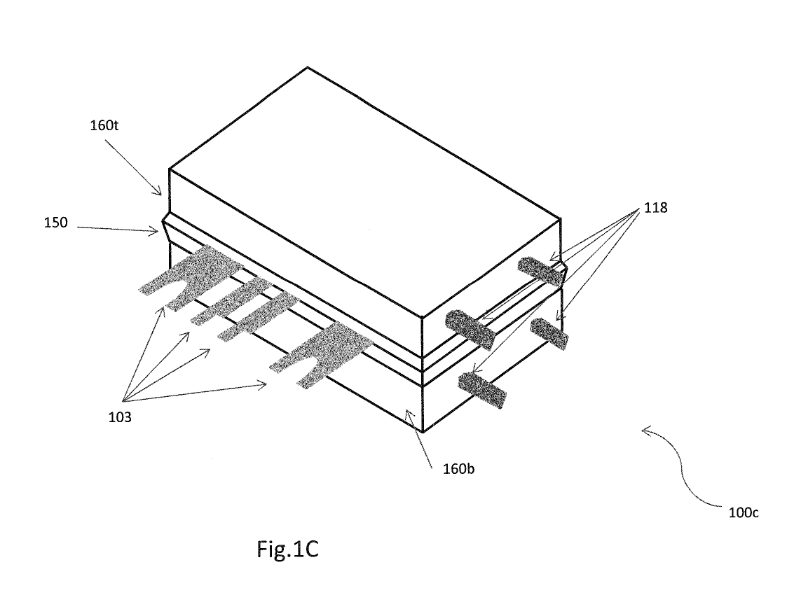

According to FIG. 1A, a cross-sectional view of a power semiconductor module according to an exemplary embodiment of the disclosure is shown. A power semiconductor module 100, as illustrated in FIG. 1A, comprises a power semiconductor part 150 interposed between two cooling module parts 160b and 160t. Power semiconductor part 150 is shown composed of power semiconductors 103 which have top sides 132 and bottom sides 134. Top sides 132 are in direct contact with spacers 106, and bottom sides 134 are mounted on substrate 110b. Typically, power semiconductors 103 can be one or more of insulated gate bipolar transistor (IGBT) 102 in parallel with diode 104. However, any electronic component, or semiconductor, expected to generate excess heat during operation may be used. Accordingly, for purposes of this disclosure, the term “power semiconductor device” or “semiconductor device” is understood to incorporate any electronic device or semiconductor chip that can be found in a package. For the reason of clarity, components limited to a pairing of IGBT 102 with diode 104 are illustrated in FIG. 1A, although any number of components may be found in the area defined by semiconductor part 150, limited only by the space available and practical considerations including for example accommodation for wiring 133 or other inter-module connections.

IGBT 102, diode 104 and spacers 106 are shown molded into mold compound 108 in such a way that mold compound 108 forms a coplanar surface 109t with top sides 136 of spacers 106. Substrate 110t is disposed on surface 109t, connected to top sides 136 of spacers 106 and the coplanar surface and in thermal contact therewith. Cooling module part 160t is situated above substrate 110t adjacent to surface 109t and likewise in thermal contact with substrate 110t. Likewise, cooling module part 160b is situated beneath substrate 110b and in thermal contact therewith. In the configuration shown, IGBT 102 and diode 104 may directly contact substrate 110b, with the result that cooling module parts 160t and 160b are respectively in thermal contact with heat generating components of power semiconductor module 100.

Each cooling module part 160b or 160t is composed of cooling shell 112t or 112b (collectively cooling shells 112) bonded to one of substrates 110b and 110t. One or both of cooling shells 112 are shaped to form a hollow fluid-tight enclosure in its interior 114 or as a cap exposing interior 114 on one open side 111t and 111b, respectively. Cooling shells 112 are shown provided with one or more coolant ports 118. Coolant ports 118 are shown having a hollow cylindrical, or pipe-like structure with one end open to the interior 114 of cooling shells 112, the other end typically extending away from the shell.

As shown, cooling shells 112t and 112b are respectively bonded to power semiconductor part 150 with open sides 111t and 111b placed respectively over substrates 110t and 110b. Typically, the perimeter formed by open side 111t or 111b is circumscribed within the perimeter of substrate 110t or 110b. In other words, the area of the opening side of cooling shells 112t or 112b is smaller than the area of substrate 110t or 110b. Typically, substrates 110t and 110b are the substrates which can provide excellent thermal conductivity, high voltage insulation at higher temperature, high mechanical strength and mechanically stability, good adhesion and corrosion resistance, and good heat spreading, for example, DCB (Direct Copper Bonding) substrates or DAB (Direct Aluminum Bonding) substrates. Substrates 110t and 110b are merely in mechanical connection 120 with cooling shells 112t and 112b respectively, and mechanical connection 120 is further molded into and sealed with mold compound 108. Accordingly, the interior 114 of cooling shells 112 are directly exposed at least in part on one side to substrates 110t and 110b, respectively.

FIG. 1B is one exemplary embodiment of detailed configuration of the mechanical connection 120 of FIG. 1A. As shown in FIG. 1B, the opening end of cooling shell 112t may contain a protruding structure such as anchor 121 extending in the direction perpendicular to the planar of substrate 110t. More particularly, anchor 121 is positioned to extend beyond the substrate 110t. Mold compound 108 may engage at least part of anchor 121, and thus physically joins cooling shell 112t to substrate 110t. Typically, the outmost perimeter of mold compound 108 is larger than the outmost perimeter of cooling shell 112t, so as to enclose anchor 121 extended from cooling shell 112t into the mold compound 108 as shown in FIG. 1B. Further, the interface between cooling shell 112t and substrate 110t is sealed with seal 123. Typically, seal 123 can be formed directly from mold compound 108. In other words, mold compound 108 serves to adhere cooling shell 112t to substrate 110t, and to provide a coolant-proof seal therebetween. Turning now back to FIG. 1A, in the present embodiment, spacers 106 are composed of thermally conductive material, e.g. metal. Coolant 116 may be composed of one of gases, liquids and mixtures of gases, liquids and solids. Typically, coolant 116 is composed of water. Cooling shell 112 is formed of any light and coolant-proof material such as, e.g. metal or plastic, metallized plastic, ceramic, epoxy, etc.

In the configuration shown in FIG. 1A, the interior 114, for example of cooling shell 112t is in thermal contact with the heat generating components of power semiconductor module 100.

In operation, IGBT 102 and diode 104 typically produce heat that is conducted to the outer surfaces of the devices. In particular, major surfaces typically comprising the top sides 132 and bottom sides 134 will rapidly increase in temperature with the result that a temperature gradient between the devices and the surrounding materials develops. The heat developed at the bottom sides 134 of IGBT 102 and diode 104 is conveyed such as by conduction through substrate 110b to cooling module part 160b. Substrates are commonly used in power semiconductor module, at least in part because of their good thermal conductivity.

Substrate 110b conveys the heat to cooling module part 160b such as by contact with the major surface, bottom side 134, of power semiconductors IGBT 102 and diode 104. Additionally, substrate 110b isolates power semiconductor part 150, especially IGBT 102 and diode 104, from direct exposure to coolant 116. Likewise, the heat developed at top sides 132 of IGBT 102 and diode 104 is conducted through spacers 106, the spacers typically having heat conductive properties exceeding those of the surrounding package material, mold compound 108 to substrate 110t. Substrate 110t forms an integral part of the cavity forming the interior 114 of cooling shell 112t, with the result that the heat that develops during operation of semiconductor components 102 and 104 is conducted to substrate 110t and thereby to cooling module part 160t. In addition, substrates 110b and 110t prevent incursion of coolant 116 into power semiconductor part 150, particularly IGBT 102 and diode 104.

As shown in FIG. 1A, cooling shells 112 are mechanically integrated to and sealed with power semiconductor part 150. Cooling shells 112 may be formed of light and coolant-proof material, for example waterproofed plastic sheet would be preferable in case water is used as coolant, because of its low weight and good heat isolation property. In addition, cooling shells 112 may prevent heat from leaking out of module 100 into the area immediately surrounding the package to protect the heat sensitive components which may be located around module 100.

Coolant ports 118 enables coolant 116 to flow in and out of the interior 114 of cooling shells 112. Ideally, multiple coolant ports or inlets/outlets 118 are provided to permit continuous flow of coolant 116, for example into one inlet 118 and out from a corresponding outlet 118. Coolant 116 can be gases, liquids or a mixture of gases, liquids and solids to absorb and transfer heat from power semiconductor part 150. Water, selected for its relatively high heat capacity, safety and abundance may be a typical example, possibly mixed with an alcohol or similar ‘antifreeze’ or ‘anti-boil’ is preferable for coolant 116 if package 100, and/or the device it is installed into, is to be hardened against extreme temperatures. Coolant flow conveys away the heat from power semiconductor part 150 transferred to the coolant during contact with a substrate 110. The water tight property of substrates 110 are relied upon to isolate power semiconductor devices IGBT 102 and diode 104 from contact with coolant 116, to prevent corrosion of power semiconductor devices that may occur depending on the fluid used. Coolant ports 118 can be ducts inserted into cooling shell 112 and sealed therewith. Alternatively, coolant ports 118 can also be integrated into cooling shell 112 during production stage of cooling shell 112.

In the present embodiment, heat generating devices IGBT 102 and diode 104 are encompassed with cooling module parts 160t and 160b from both top and bottom sides, and that provides an all-round, or more accurately two-side, cooling environment. The utilization of plastic cooling shells 112 and water for coolant 116 can provide good thermal dissipation at very low cost. In addition, since cooling module parts 160b and 160t are integrated to and sealed with power semiconductor part 150 in the production stage, the market value of power semiconductor module 100 is increased, and system designers and end users may avoid extensive assembly of cooling system parts and power semiconductor parts.

FIG. 1C is a power semiconductor product 100c with double-sided cooling modules 160t and 160b in accordance with the embodiment illustrated in FIG. 1A. Power semiconductor 100c is composed of power semiconductor part 150 and cooling module parts 160t and 160b. A plurality of power semiconductors 103 are molded into power semiconductor part 150, and inlet/outlet ducts 118 are inserted into cooling module parts 160t and 160b.

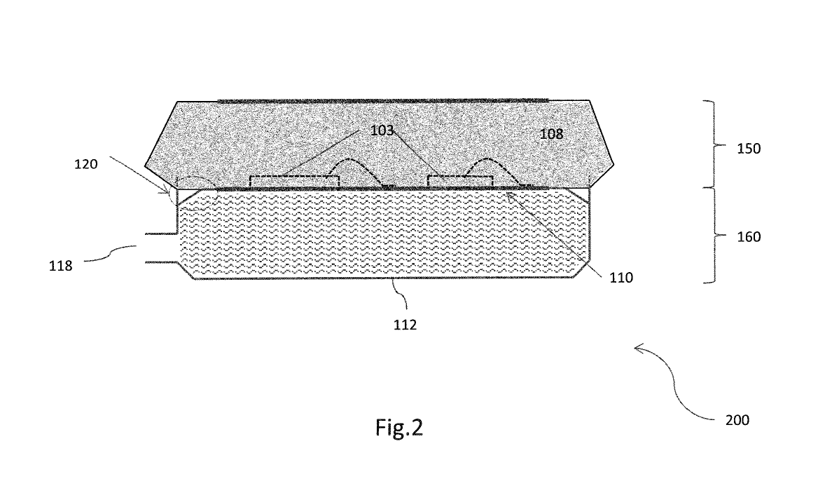

In some exemplary embodiments, merely one cooling module is mounted onto a power semiconductor part which generates heat, as depicted in FIG. 2. FIG. 2 illustrates a single-side cooling module 160 integrated with a power semiconductor part 150. As shown in FIG. 2, cooling module 160 is typically mounted to the side that is closer to the heat generation power semiconductors.

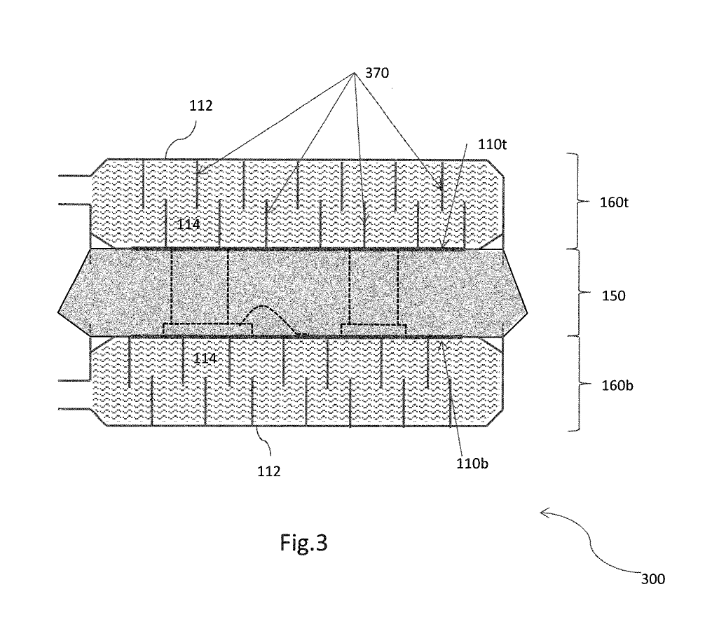

In one exemplary embodiment, cooling module parts 160b and 160t may comprise a set of cooling fins 370, as illustrated in FIG. 3. Fins 370 can be implemented in the interior 114 of cooling shell 112, such as in an alternating pattern creating a meander or labyrinth channel. The fins 370 may also be implemented as heat conductive surfaces, effectively increasing the surface area in the interior 114 of cooling shell 112 for effectively transferring the heat from power semiconductor part 150 to coolant 116. In addition, cooling fins 370 can also be implemented as division plates for increasing contact areas or for slowing and directing the flow of coolant 116. It is to be understood that the cooling fins 370 depicted in FIG. 3 are merely one exemplary embodiment of the cooling module of the present disclosure, and that any suitable cooling fins pattern which functions as heat conduction and coolant division may be implemented. For example, although the exemplary cooling fins 370 are depicted as mounted to both top and bottom surfaces of cooling module part 160t or 160b, it is to be understood that cooling fins 370 may be mounted merely on substrates 110t and 110b. Moreover, well or drop cooling fins structure inside cooling shell 112 may be provided, in order to make the cooling module more efficient.

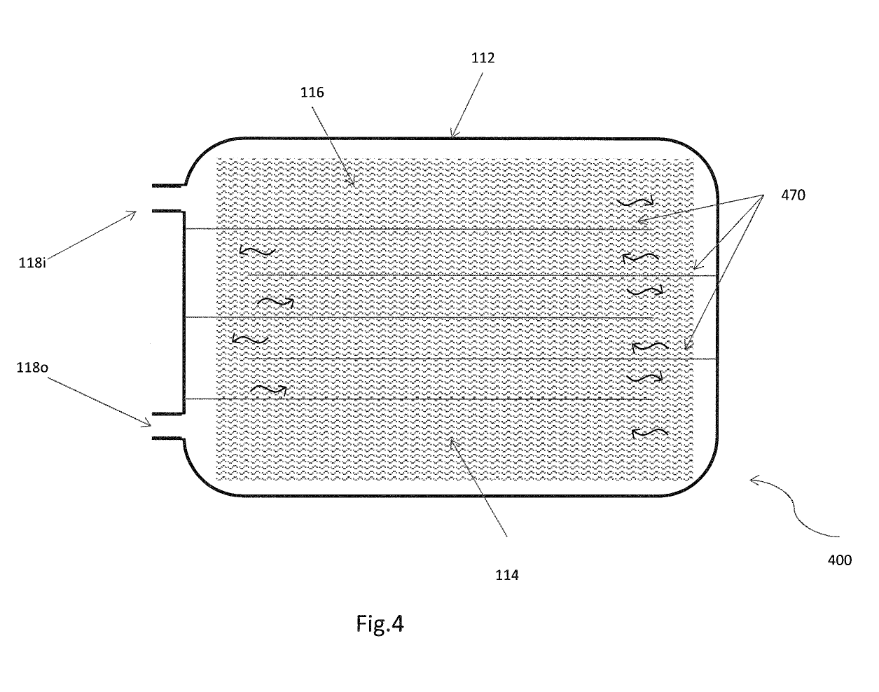

In another embodiment, in order to improve the thermal properties of cooling structure, meandering channels are provided inside cooling shell 112 as illustrated in FIG. 4. In particular, FIG. 4 depicts a top cross-section view of a cooling module part 400 which comprises channel walls 470 inside cooling shell 112. Channel walls 470 divide the interior 114 of cooling shell 112 into a set of channels. Coolant fluid 116 flows into the channels from inlet duct 118i, and then is heated by absorbing heat from the channel walls 470 and exits through outlet duct 118o. The arrows denote the coolant flow direction. Advantageously, the contact areas of coolant 116 are increased due to channel walls 470, therefore, the heating conduction is more efficiently.

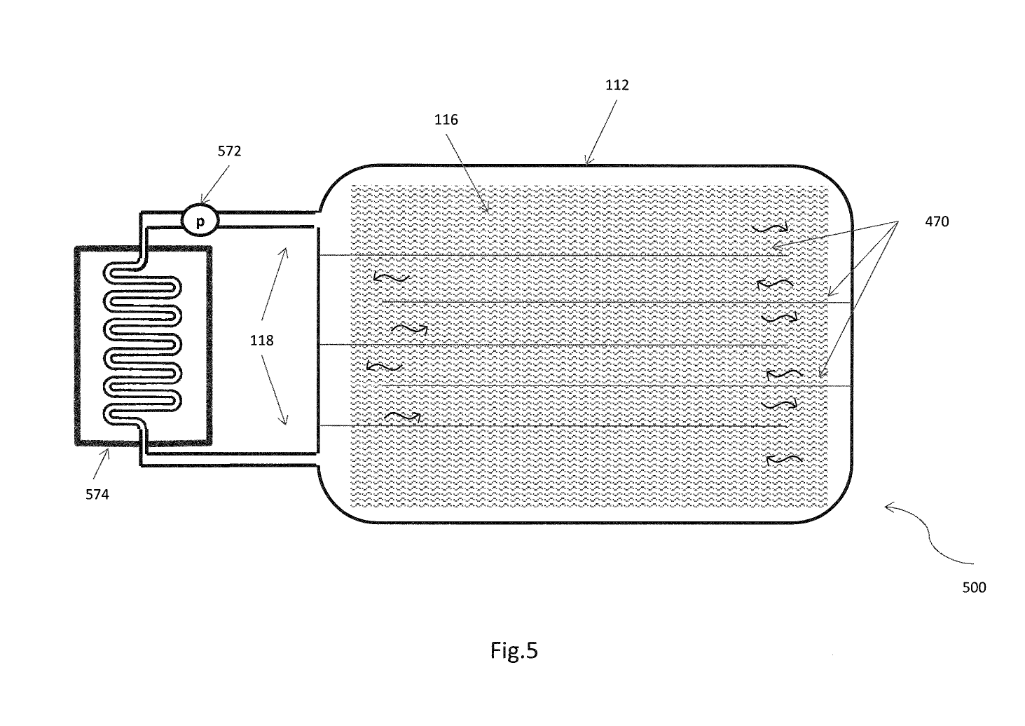

In another embodiment, a pump 572 may be placed between coolant ports 118 and heat exchanger 574 as illustrated in FIG. 5. Pump 572 is configured to control the flow of coolant 116 in the cooling shell 112, and to facilitate pour-in and extraction of coolant 116. The pump can be an existing one in the device incorporating power semiconductor module 100, or it can also be a dedicated pump. In operation, provision is typically made to expose heat exchanger 574 to a heat sink, such as air, or a secondary loop of chilled liquid. Heat drawn away from heat exchanger 574 may be vented into the ambient environment, or transferred to a second cooling system (not shown).

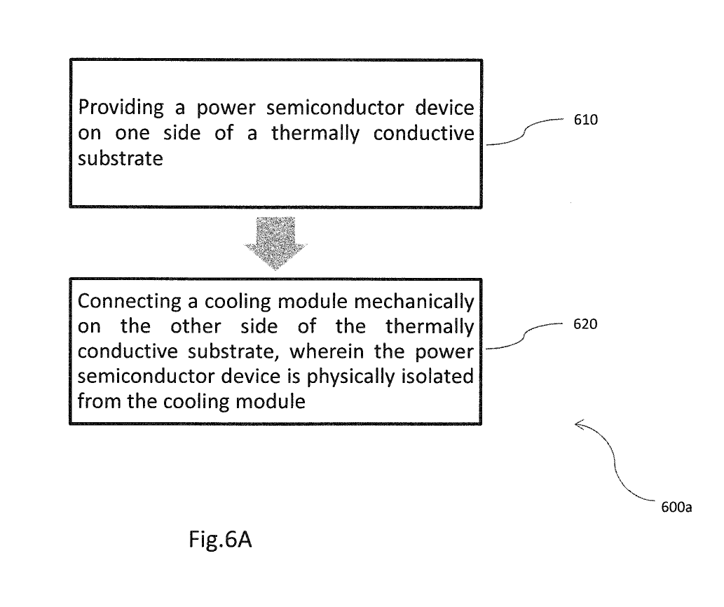

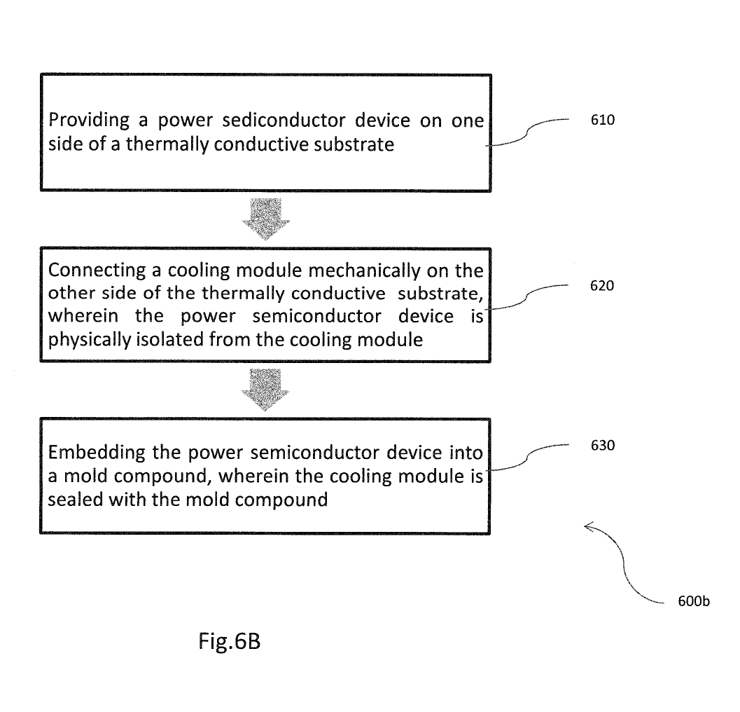

In one embodiment, a method 600a for producing a power semiconductor device with a cooling module is provided in FIG. 6A. In 610, a power semiconductor device is deposited on one side of a thermally conductive substrate. The thermally conductive substrate can be a DCB or a DAB substrate. In 620, a cooling module is connected mechanically on the other side of the thermally conductive substrate. The power semiconductor device is therefore physically isolated from the cooling module.

The method for producing a power semiconductor device with a cooling module may further include embedding the power semiconductor device into a mold compound and sealing the cooling module with the mold compound as shown in 630 of FIG. 6B.

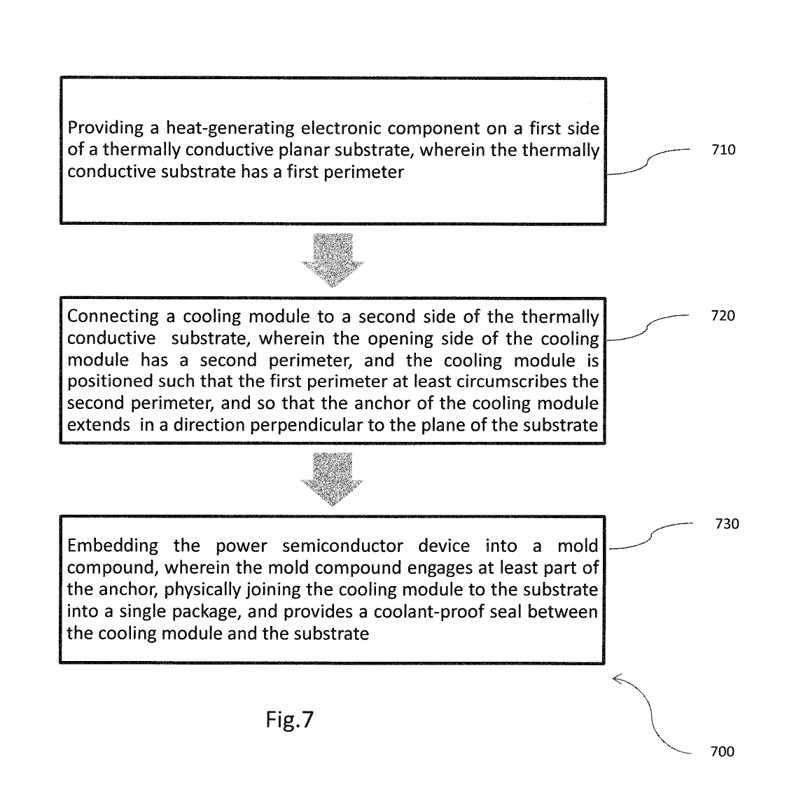

In a further method as shown in FIG. 7 in accordance with the present disclosure, a power semiconductor device or similar heat-generating electronic component is provided in 710 on a first side of a substrate, for example a thermally conductive substrate such as a DCB or DAB wherein the thermally conductive substrate has a first perimeter. For example, such substrate 110t or 110b is shown and described in reference to FIG. 1. In 720, a cooling module is positioned in thermal contact with the substrate, for example advantageously on a second side thereof. As disclosed above, the cooling module may form a shell such as cooling shell 112 of FIGS. 1-5, having an interior cavity 114. The shell may be completely enclosed, or may have an opening on one side, the opening having a second perimeter, advantageously smaller than the first perimeter. More specifically, the cooling module may advantageously be positioned such that the first perimeter at least circumscribes the second perimeter.

In this position, the dimensions of the cooling module may be projected onto the substrate such that at least a portion of cooling shell 112 extends outside the first perimeter. A protruding structure such as anchor 121 (as shown, for example, in FIG. 1B) may extend past the substrate in this position. More particularly, the anchors are positioned to extend beyond the substrate from the second side to the first side thereof.

In 730, a mold material, or similar intervening structure is formed on the first side of the substrate. Advantageously, the mold material may cover all of the semiconductor devices, and related structures such as electrical contacts, wiring, thermally conductive structures (such as spacers 106 as shown for example in FIG. 1) and extending at least as far on the substrate to circumscribe the first perimeter, i.e. the perimeter of the substrate. Additionally, the mold material advantageously engages or covers at least part of anchor 121 extending from the cooling module. Thus, the mold material, which may be applied as a liquid that later hardens (for example an epoxy material) physically joins the cooling module to the substrate into a single package, the package including an integrated cooling module.

Further, and advantageously, the mold material may serve to seal the interface between the cooling module and the second side of the substrate. In particular, where the cooling module forms a cavity, such as cavity 114 having an opening side such as opening lilt or 111b as shown in FIG. 1A defining a second perimeter circumscribed by the (first) perimeter of the substrate, such as substrate 110t or 110b, a seal, such as seal 123 as shown in FIG. 1B may be formed by the mold material itself. More particularly, mold material 108 may serve to adhere the cooling module to the substrate, and to provide a coolant-proof seal therebetween.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. A semiconductor module comprising:
at least one heat generating device, wherein the at least one heat generating device has first and second planar sides;
a first thermally conductive structure in thermal contact with the first planar side of said heat generating device;
an intervening layer, wherein the at least one heat generating device is embedded therein;
a first cooling module defining a first cavity, said first cavity in thermal contact with said first thermally conductive structure, and said first cooling module in mechanical connection with said first thermally conductive structure, wherein said mechanical connection contains at least an anchor molded into said intervening layer;
a first inlet provided in said first cavity for receiving a coolant;
a first outlet provided in said first cavity for discharging said coolant;
wherein said heat generating device is in coolant-proof isolation from said cavity.

2. The semiconductor module of claim 1, wherein said heat generating device is a power semiconductor device.

3. The semiconductor module of claim 2, wherein said power semiconductor device comprises an insulated-gate bipolar transistor (IGBT) in parallel with a diode.

4. The semiconductor module of claim 1, wherein said first thermally conductive structure is one of the substrates from a direct copper bonding (DCB) substrate and a direct aluminum bonding (DAB) substrate.

5. The semiconductor module of claim 1, wherein said first cooling module is composed of coolant-proof material.

6. The semiconductor module of claim 1, wherein said first cooling module is composed of plastic.

7. The semiconductor module of claim 1, wherein said coolant is composed of one of gases, liquids and mixtures of gases, liquids and solids.

8. The semiconductor module of claim 1, wherein said coolant is composed of water.

9. (canceled)

10. (canceled)

11. The semiconductor module of claim 1, wherein said intervening layer is composed of mold compound.

12. The semiconductor module of claim 1, further comprising:
at least one thermally conductive spacer embedded in said intervening layer, said thermally conductive spacer having first and second planar sides, wherein the first planar side of said thermally conductive spacer is bonded to the second planar side of said heat generating device;
a second thermally conductive structure in thermal contact with the second planar side of said thermally conductive spacer;
a second cooling module defining a second cavity, said second cavity in thermal contact with said second thermally conductive structure, and said second cooling module in mechanical connection with said second thermally conductive structure; and
a second inlet provided in said second cavity for receiving said coolant;
a second outlet provided in said second cavity for discharging said coolant.

13. The semiconductor module of claim 12, wherein said intervening layer forms a coplanar surface with the second planar side of said thermally conductive spacer.

14. The semiconductor module of claim 13, wherein said second thermally conductive structure is one of the substrates from a direct copper bonding (DCB) substrate and a direct aluminum bonding (DAB) substrate

15. The semiconductor module of claim 12, wherein said second cooling module is composed of coolant-proof material.

16. The semiconductor module of claim 12, wherein said second cooling module is composed of plastic.

17. The semiconductor module of claim 12, wherein at least one from the set composed of the first inlet, the first outlet, the second inlet and the second outlet, connects to a pump.

18. The semiconductor module of claim 12, wherein at least one of the first cooling module and the second cooling module contains cooling fins.

19. The semiconductor module of claim 12, wherein at least one of the first cooling module and the second cooling module contains a plurality of channel walls.

20. A method for producing a power semiconductor device with a cooling module comprising:
providing said power semiconductor device on a first side of a thermally conductive substrate, wherein said thermally conductive substrate has a first perimeter;
connecting said cooling module mechanically on a second side of said thermally conductive substrate, wherein said cooling module has at least one protruding structure extending in the direction from the second side to the first side of said thermally conductive substrate; and
embedding said power semiconductor device into a mold compound, wherein said mold compound engages at least part of said at least one protruding structure, physically joins said cooling module to said thermally conductive substrate into a single package, and provides a coolant-proof seal between said cooling module and said thermally conductive substrate.
